(19) United States
(12) Patent Application Publication
(10) Pub. No.: US 2026/0106435 A1
(43) Pub. Date: Apr. 16, 2026

(54) Multi-Junction, Polarization-Controlled Vertical Cavity Surface Emitting Laser and Method of Fabrication Thereof

(71) Applicant: II-VI Delaware, Inc., Wilmington, DE (US)

(72) Inventors: Fabio Isa, Zürich (CH); Lukas Mutter, Uster (CH); Norbert Lichtenstein, Stallikon (CH)

(21) Appl. No.: 18/911,378

(22) Filed: Oct. 10, 2024

(51) Int. Cl. H01S 5/183

(52) U.S. Cl. CPC H01S 5/18327; H01S 5/18311; H01S 5/18355

(57) ABSTRACT

Disclosed is a vertical cavity surface emitting laser (VCSEL) and a method of fabricating or forming the VCSEL that includes from a bottom to a top of the VCSEL a semiconductor substrate, a bottom distributed Bragg reflector (DBR), a semiconductor active region including at least one active subregion, and a top DBR. A dielectric layer may be included between the bottom DBR and the semiconductor active region including the at least one active subregion or the semiconductor active region may include two active subregions without the dielectric layer between the bottom DBR and the semiconductor active region. The VCSEL may also include a grating structure.

### BACKGROUND

### 1) Field

The present disclosure relates to vertical cavity surface emitting lasers (VCSELs) and, in particular, a method of fabricating VCSELs.

### 2) Background

In connection with VCSELs, there is an ongoing desire to increase wafer fusion yield, stability, thermal conductivity to the substrate, the efficiency of a VCSEL to convert electrical input power into optical output power, also known as “slope”, and to control the VCSEL's light emission polarization.

### SUMMARY

Disclosed herein are VCSELs, e.g., IR VCSELs, and methods of fabrication thereof by wafer fusion of a second semiconductor wafer, that includes one or more active regions, and a first semiconductor wafer that includes a first distributed Bragg reflector (DBR) with an optional low refractive index material between the first and second semiconductor wafers; and forming multi-junctions and a current confinement structure before or after fusing the two wafers.

Also disclosed is VCSEL light emission polarization control by forming a polarization control structure: (1) on or within the layers of a second DBR or a semiconductor layer adjacent to the second DBR; or (2) a layer of the first semiconductor wafer at or adjacent the wafer fusion interface of the first and second semiconductor wafers. In an example, each polarization control structure may comprise a grating structure.

Wafer Fusion: More specifically, disclosed is fabrication of VCSELs by wafer fusion between a second semiconductor wafer comprising a second stack of semiconductor layers including one or more active regions and a first semiconductor wafer comprising a first stack of semiconductor layers including a first DBR, with an optional low refractive index dielectric layer (hereinafter sometimes referred to as “dielectric layer”) disposed between the first and second wafers. In this disclosure, it is intended that each instance of “dielectric layer” is to be interpreted and construed as being “optional”, i.e., an “optional dielectric layer”. Stated differently, each instance of “dielectric layer” in this disclosure is be interpreted and construed as being preceded by the word “optional”.

In this disclosure, the dielectric layer may fulfil the requirement of λx/4 optical thickness, i.e., the dielectric layer may have a thickness of λx/4, wherein x is an odd number, e.g., 1, 3, 5, etc. and λ is a wavelength of the optical signal, e.g., of IR light, to be produced by the VCSEL. The dielectric layer may be formed as a contiguous layer on either the first or second semiconductor wafer whereupon, after wafer fusion of the first and second semiconductor wafers, the dielectric layer may be disposed between the first and second semiconductor wafers. Alternatively, the dielectric layer may be formed by depositing portions of the dielectric layer on both of the first and second semiconductor wafers, whereupon, after wafer fusion at the interface of the portions of the dielectric layer deposited on both of the first and second semiconductor wafers, the dielectric layer has the thickness of λx/4, wherein x is an odd number and λ is a wavelength of the optical signal to be produced by the VCSEL.

Wafer fusion between the first and second semiconductor wafers with the dielectric layer having the λx/4 thickness therebetween may solve the problem of requiring the first DBR to a have large number of semiconductor DBR layers for the VCSEL. To this end, it is envisioned that the same first DBR reflectivity may be achieved with a lesser number of semiconductor DBR layer pairs compared to the case of wafer fusion without the dielectric layer having the λx/4 thickness between the first and second semiconductor wafers. By reducing the number of semiconductor DBR layer pairs, bow of the fabricated VCSEL may be diminished, wafer fusion yield and stability of the wafer fusion may be improved, and thermal conductivity through the first and second DBRs and a substrate of the first semiconductor wafer may be improved.

Slope Increase: The slope of the VCSEL formed by the fusion of the first and second semiconductor wafers with the dielectric layer therebetween may also be improved, e.g., multiplied, by the second semiconductor wafer including one or, desirably, more semiconductor active regions. In an example, each semiconductor active region may comprise a quantum well layer positioned on one side of a pair of cavity regions or layers that are separated from each other by a tunnel junction layer to allow current flow between top and bottom electrical contacts of the VCSEL. In another example, each semiconductor active region may comprise a tunnel junction layer positioned on one side of a pair of cavity regions or layers that are separated from each other by a quantum well layer to allow current flow between the top and bottom electrical contacts of the VCSEL.

In this disclosure, the locations of the top and bottom electrical contacts of each disclosed VCSEL are not specifically described or shown in the figures for the purpose of simplicity. However, one skilled in the art of the present disclosure would understand that each disclosed VCSEL includes top and bottom electrical contacts for the application of an electrical bias to the VCSEL for its operation and would understand where to locate said top and bottom electrical contacts.

In this disclosure, current confinement may be improved by adding to the second semiconductor wafer prior to fusion with the first semiconductor wafer an additional (or top) cavity layer above the highest of the semiconductor active regions of the second semiconductor wafer.

After fusion of the first and second semiconductor wafers, the substrate of the second semiconductor wafer may be selectively removed. By forming the current confinement structure, e.g., by oxidation (to form an oxide aperture), ion implantation, or by structuring and overgrowth, prior to or after fusion of the first and second semiconductor wafers, with or without the dielectric layer between the first and second semiconductor wafers, and removal of the substrate of the second semiconductor wafer, fusion yield has been observed to be remarkably increased. To this end, the surfaces of the first and second semiconductor wafers which are fused together, with or without the dielectric layer between the first and second semiconductor wafers, are not exposed to a fabrication step that may introduce one or more surface contaminants, e.g. photoresist (necessary for ion implantation), nor is the morphology altered by structuring and overgrowth. Surface contaminants and non-planar or rough surface morphology strongly limit wafer fusion yield and stability.

Light polarization control: After fusion of the first and second semiconductor wafers, with or without the dielectric layer between the first and second semiconductor wafers, and removal of substrate of the second semiconductor wafer, a second DBR of the VCSEL may be added in place of the removed substrate of the second semiconductor wafer. The second DBR may be made of low absorption dielectric layers. In an example, the second DBR may include a grating structure or layer as a polarization control structure to control light polarization of the VCSEL. In an example, this grating structure or layer may be formed between a pair of layers of the second DBR. In another example, this grating structure may be formed on the top or bottom layer of the second DBR. In an example, each line of the grating structure or layer may have a grating height h (see FIG. 5) between zero and a quarter wave.

In another example, polarization control may also or alternatively take place at the fusion interface of the first and second semiconductor wafers. In an example, a grating structure or layer as a polarization control structure to control light polarization of the VCSEL may be formed of the material forming the dielectric layer of the first semiconductor substrate. In an example, this grating structure may be formed on top of the dielectric layer of the first semiconductor substrate prior to fusion with the second semiconductor wafer. In another example, this grating structure may be formed on top of the top cavity layer of the second semiconductor substrate prior to fusion with the first semiconductor wafer. In an example, each line of the grating structure or layer may have a grating height h (see FIG. 6) between zero and a quarter wave. In an example, this grating structure or layer at the fusion interface of the first and second semiconductor wafers may be formed prior to fusion of the of the first and second semiconductor wafers.

Disclosed herein is method of fabricating a vertical cavity surface emitting laser (VCSEL) comprising: (a) forming or providing a first semiconductor wafer comprising, from a bottom to a top thereof, a first semiconductor substrate and a bottom distributed Bragg reflector (DBR); (b) forming or providing a second semiconductor wafer comprising, from a bottom to a top thereof, a second semiconductor substrate and a semiconductor active region comprising at least one active subregion and a top cavity layer on a side of the at least one active subregion opposite the second semiconductor substrate, wherein each active subregion comprises: a pair of cavity layers separated by a tunnel junction layer and a quantum well layer on a side of the pair of cavity layers opposite the second semiconductor substrate, or a pair of cavity layers separated by a quantum well layer and a tunnel junction layer on a side of the pair of cavity layers opposite the second semiconductor substrate; (c) coupling the bottom DBR and the semiconductor active region with the second semiconductor substrate disposed on a side of the semiconductor active region opposite the bottom DBR and then removing the second semiconductor substrate; (d) following the removal of the second semiconductor substrate, forming on a side of the semiconductor active region opposite the bottom DBR a top DBR; and (e) forming on all or part of the at least one active subregion of the semiconductor active region a current confinement structure.

In the method, step (b) may include the semiconductor active region including two active subregions; or step (c) may include coupling the bottom DBR and the semiconductor active region with a dielectric layer therebetween.

Also disclosed is vertical cavity surface emitting laser (VCSEL) comprising from a bottom to a top thereof: a semiconductor substrate; a bottom distributed Bragg reflector (DBR); a semiconductor active region comprising at least one active subregion; and a top DBR.

The VCSEL may also include one of the following: a dielectric layer between the bottom DBR and the semiconductor active region; or the semiconductor active region includes two active subregions.

### BRIEF DESCRIPTION OF THE DRAWINGS

FIG. 1A is a schematic cross-section of example first and second semiconductor wafers that may be fused together to form a first example VCSEL in accordance with the principles of the present disclosure;

FIGS. 1B-1G are schematic cross-sections of different example semiconductor active regions that may comprise the second semiconductor wafer shown in FIG. 1A;

FIGS. 2-5 are schematic cross-sections of the assembled first and second semiconductor wafers shown in FIG. 1A including further fabrication steps to form different versions of the first example VCSEL in accordance with the principles of the present disclosure;

FIG. 6 is a schematic cross-section of example first and second semiconductor wafers that may be fused together to form a second example VCSEL in accordance with the principles of the present disclosure;

FIG. 7 is a schematic cross-section of the assembled first and second semiconductor wafers shown in FIG. 6 including further fabrication steps to form the second example VCSEL in accordance with the principles of the present disclosure; and

FIG. 8 is an isolated cross-section of another example dielectric layer that may be used in replacement of the dielectric layers shown in FIGS. 1-7, but including, in the body of the dielectric layer, voids, spaces, or pockets that include no material.

### DETAILED DESCRIPTION

As used herein, spatial or directional terms, such as “left”, “right”, “inner”, “outer”, “above”, “below”, and the like, relate to the disclosure as it is shown in the drawing figures. However, it is to be understood that the disclosure can assume various alternative orientations and, accordingly, such terms are not to be considered as limiting. Further, as used herein, all numbers expressing dimensions, physical characteristics, processing parameters, quantities of ingredients, reaction conditions, and the like, used in the specification and claims are to be understood as being modified in all instances by the term “approximately” or “about”. Accordingly, unless indicated to the contrary, the numerical values set forth in the following specification and claims may vary depending upon the desired properties sought to be obtained by the present disclosure.

At the very least, and not as an attempt to limit the application of the doctrine of equivalents to the scope of the claims, each numerical value should at least be construed in light of the number of reported significant digits and by applying ordinary rounding techniques. Moreover, all ranges disclosed herein are to be understood to encompass the beginning and ending range values and any and all subranges subsumed therein. For example, a stated range of “1 to 10” should be considered to include any and all subranges between (and inclusive of) the minimum value of 1 and the maximum value of 10; that is, all subranges beginning with a minimum value of 1 or more and ending with a maximum value of 10 or less, e.g., 1 to 3.3, 4.7 to 7.5, 5.5 to 10, and the like. “A” or “an”refers to one or more.

As used herein, “coupled”, “coupling”, and similar terms refer to two or more elements that are joined, linked, fastened, connected, put in communication, or otherwise associated (e.g., mechanically, electrically, fluidly, optically, electromagnetically) with one another. In various examples, the elements may be associated directly or indirectly. As an example, element A may be directly associated with element B. As another example, element A may be indirectly associated with element B, for example, via another element C. It will be understood that not all associations among the various disclosed elements are necessarily represented. Accordingly, couplings other than those depicted in the figures may also exist.

As used herein, the phrase “at least one of”, when used with a list of items, means different combinations of one or more of the listed items may be used and only one of each item in the list may be needed. For example, “at least one of item A, item B, and item C” may include, without limitation, item A or item A and item B. This example also may include item A, item B, and item C, or item B and item C. In other examples, “at least one of” may be, for example, without limitation, two of item A, one of item B, and ten of item C; four of item B and seven of item C; and other suitable combinations.

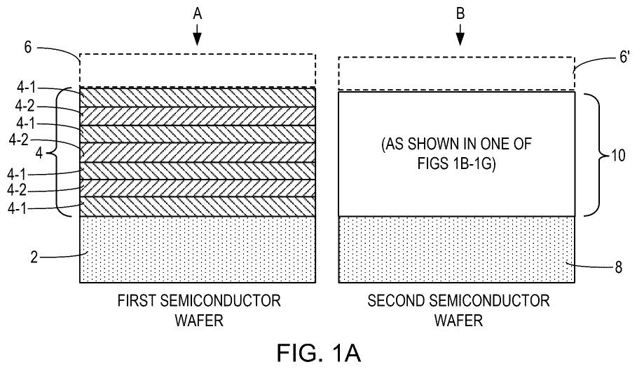

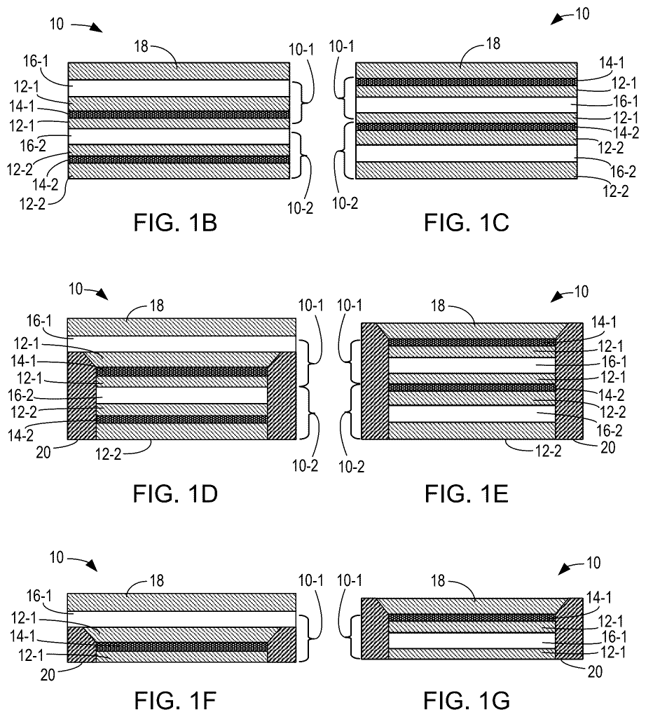

With reference to FIG. 1A, a non-limiting example of a method of fabricating a first example vertical cavity surface emitting laser (VCSEL) in accordance with the principles of the present disclosure may comprise a Step A, wherein a first semiconductor wafer A comprising a first stack of semiconductor layers is provided. In an example, the first stack of semiconductor layers may comprise, from a bottom to a top thereof, a first semiconductor substrate 2 and a bottom distributed Bragg reflector (DBR) 4.

In an example, the bottom DBR 4 may be formed of one or more pairs of alternating layers 4-1 and 4-2 of low and high refractive index materials such as, for example, AlAs and GaAs, respectively. However, this is not to be construed as limiting since the bottom DBR 4 may be formed of alternating layers of any suitable and/or desirable materials now known or hereafter developed that enable the bottom DBR 4 to function or operate in a manner known in the art. In an example, the alternating layers 4-1 and 4-2 of the bottom DBR 4 may have refractive indices ≤3.0 (e.g., 2.95) and >3.4 (e.g., 3.45), respectively. In an example, each layer 4-1 and 4-2 may have a thickness of λx/4, where x is an odd number, e.g., 1, 3, 5, etc., and λ is a wavelength of the signal to be produced by the VCSEL.

With continuing reference to FIG. 1A, the method may further comprise a Step B, wherein a second semiconductor wafer B comprising a second stack of semiconductor layers may be provided. In an example, the second stack of semiconductor layers may comprise, from a bottom to a top thereof, a second semiconductor substrate 8 and a semiconductor active region 10 that may comprise any one or combination of the structures shown as oriented in FIGS. 1B-1G.

In an example, the semiconductor active region 10 in FIG. 1A may comprise the semiconductor active region 10 shown in FIG. 1B comprising one or more active subregions 10-1, 10-2, and a top cavity layer 18. Each active subregion 10-1, 10-2 may comprises a pair of cavity layers 12 separated by a tunnel junction layer 14 and a quantum well layer 16 on a side of the pair of cavity layers 12 opposite the second semiconductor substrate 8. In the case where semiconductor active region 10 of the second semiconductor wafer B in FIG. 1A includes the semiconductor active region 10 shown in FIG. 1B, the first and second active subregions 10-2 and 10-1 may include, in order from the second semiconductor substrate 8 to the top cavity layer 18: the active subregion 10-2 comprising a cavity layer 12-2, a tunnel junction layer 14-2, another cavity layer 12-2, and a quantum well layer 16-2; and the active subregion 10-1 comprising a cavity layer 12-1, a tunnel junction layer 14-1, another cavity layer 12-1, and a quantum well layer 16-1.

In another example, the semiconductor active region 10 in FIG. 1A may comprise the semiconductor active region 10 shown in FIG. 1C which is similar in many respects to the structure shown in FIG. 1B except as follows: the positions of the tunnel junction layers 14 and the quantum well layers 16 in FIG. 1B are reversed in FIG. 1C. In the case where semiconductor active region 10 of the second semiconductor wafer B in FIG. 1A includes the semiconductor active region 10 shown in FIG. 1C, the first and second active subregions 10-2 and 10-1 may include, in order from the second semiconductor substrate 8 to the top cavity layer 18: the active subregion 10-2 comprising a cavity layer 12-2, a quantum well layer 16-2, another cavity layer 12-2, and a tunnel junction layer 14-2; and the active subregion 10-1 comprising a cavity layer 12-1, a quantum well layer 16-1, another cavity layer 12-1, and a tunnel junction layer 14-1.

In another example, the semiconductor active region 10 of the second semiconductor wafer B in FIG. 1A may include the semiconductor active region 10 shown in FIG. 1D which is similar to the semiconductor active region 10 shown in FIG. 1B with the addition of a current confinement structure 20 formed surrounding, from the bottom to the top in FIG. 1D: all of the active subregion 10-2 comprising the cavity layer 12-2, the tunnel junction layer 14-2, the other cavity layer 12-2, the quantum well layer 16-2; and part of the active subregion 10-1 comprising the cavity layer 12-1, the tunnel junction layer 14-1, and the other cavity layer 12-1, but not the quantum well layer 16-1.

In another example, the semiconductor active region 10 of the second semiconductor wafer B in FIG. 1A may include the semiconductor active region 10 shown in FIG. 1E which is similar to the semiconductor active region 10 shown in FIG. 1C with the addition of a current confinement structure 20 formed surrounding, from the bottom to the top in FIG. 1E: all of the active subregion 10-2 comprising, the cavity layer 12-2, the quantum well layer 16-2, the other cavity layer 12-2, the tunnel junction layer 14-2; all of the active subregion 10-1 comprising the cavity layer 12-1, the quantum well layer 16-1, the other cavity layer 12-1, and the tunnel junction layer 14-1; and the top cavity layer 18.

In another example, the semiconductor active region 10 of the second semiconductor wafer B in FIG. 1A may include the semiconductor active region 10 shown in FIG. 1F which is similar to the semiconductor active region 10 shown in FIG. 1D with the exclusion of the active subregion 10-2 and the portion of the current confinement structure 20 surrounding the excluded active subregion 10-2.

In another example, the semiconductor active region 10 of the second semiconductor wafer B in FIG. 1A may include the semiconductor active region 10 shown in FIG. 1G which is similar to the semiconductor active region 10 shown in FIG. 1E with the exclusion of the active subregion 10-2 and the portion of the current confinement structure 20 surrounding the excluded active subregion 10-2.

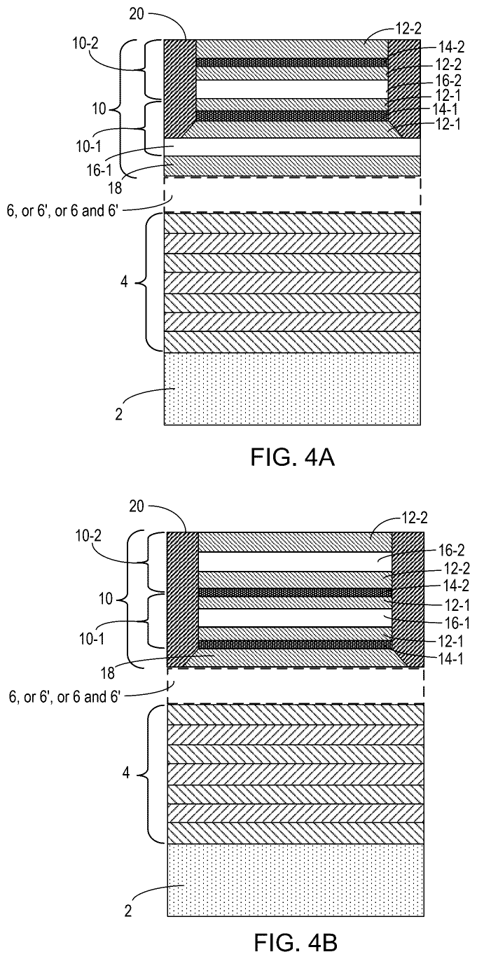

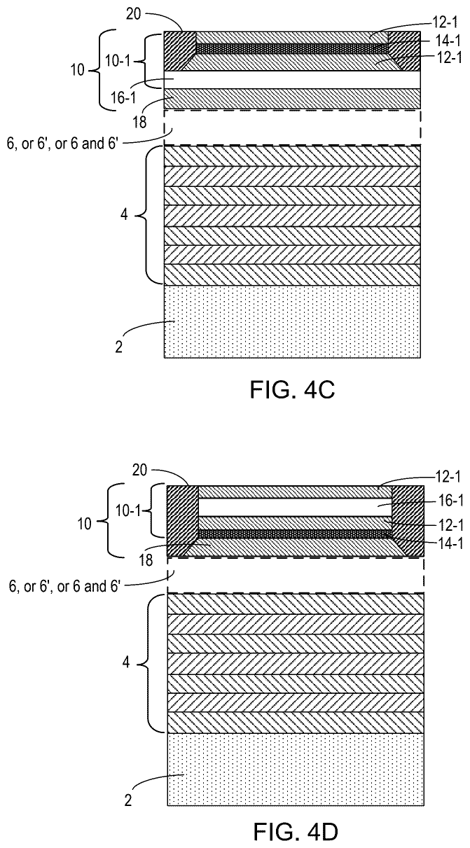

In an example, where the semiconductor active region 10 in FIG. 1A comprises the structure shown in FIG. 1B or 1C, the current confinement structure 20 may be formed after wafer fusion of the first and second semiconductor wafers A and B as described hereinafter in connection with any one of FIGS. 4A-4D. In other words, Step B may comprise providing the second semiconductor wafer B including the semiconductor active region 10 shown in FIG. 1B or 1C without a current confinement structure 20 which may be added later, after wafer fusion of the first and second semiconductor wafers A and B.

In contrast, where the semiconductor active region 10 of the second semiconductor wafer B in FIG. 1A comprises the structure shown in any one of FIGS. 1D-1G, the current confinement structure 20 may be formed prior to wafer fusion of the first and second semiconductor wafers A and B described hereinafter. In other words, Step B may comprise providing the second semiconductor wafer B comprising the semiconductor active region 10 including the current confinement structure 20 shown in any one of FIGS. 1D-1G.

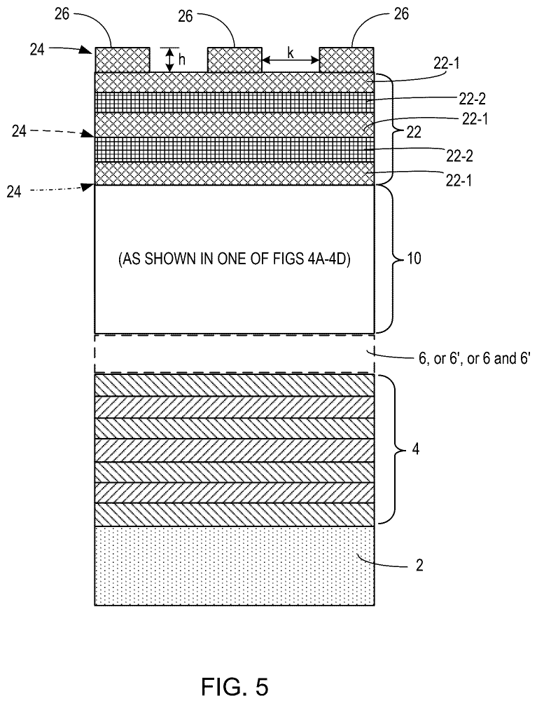

Regardless of when the current confinement structure 20 is introduced, i.e., prior to or after wafer fusion, the aim after wafer fusion is to provide the structure shown in any one of FIG. 4A4D for further processing as shown and described in connection with FIG. 5.

In an example, each example current confinement structure 20 described herein may be formed by oxidation (to form an oxide aperture), ion implantation, or by etching and overgrowth all or part of the sides of the one or more active subregions 10-1 and 10-2.

In an example, each cavity layer 12 may be formed of InP, each tunnel junction layer 14 may be formed of alternating sublayers (not specifically shown in the figures) of InAlGaAs p++ and InAlGaAs n−−, and each quantum well layer 16 may be formed of alternating sublayers (not specifically shown in the figures) of InGaAsP with different ratios of InGa. However, this is not to be construed as limiting since layer(s) 12, 14, and/or 16 may be formed of any suitable and/or desirable material(s) now known or hereafter developed that enable the layer(s) 12, 14, and/or 16 to function or operate in a manner known in the art.

In an example, the top cavity layer 18 may be formed of InP. However, this is not to be construed as limiting since the top cavity layer 18 may be formed of any suitable and/or desirable materials now know or hereafter developed that enable the top cavity layer 18 to function or operate in a manner known in the art.

In an example, Step A may comprise the first semiconductor wafer A including a dielectric layer 6 (shown in dashed lines in FIG. 1A), or a portion thereof, on a side of the bottom DBR 4 opposite the first semiconductor substrate 2. Also or alternatively, in another example, Step B may comprise the second semiconductor wafer B including a dielectric layer 6′ (shown in dashed lines in FIG. 1A), or a portion thereof, on a side of the semiconductor active region 10 opposite the second semiconductor substrate 8.

Steps A and B may be completed in any desired order.

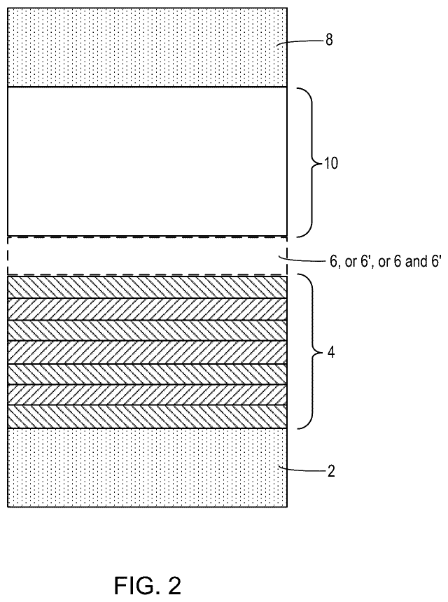

With reference to FIG. 2 and with continuing reference to FIG. 1, following Steps A and B, the method may comprise a Step C, wherein the first and second semiconductor wafers A and B may be joined or coupled together, e.g., by fusion, of the bottom DBR 4 and the semiconductor active region 10 and the dielectric layer(s) 6, or 6′, or 6 and 6′ disposed between the bottom DBR 4 and the semiconductor active region 10. In FIG. 2, the dielectric layer(s) 6, or 6′, or 6 and 6′ may be formed of the dielectric layer 6 shown in FIG. 1A, or the dielectric layer 6′ shown in FIG. 1A, or the portions of the dielectric layers 6 and 6′ shown in FIG. 1A, respectively.

In an example, if, in Step A, the first semiconductor wafer A includes (as shown in FIG. 1A) the entirety of the dielectric layer 6 disposed on a side of the bottom DBR 4 opposite the first semiconductor substrate 2, and if, in Step B, the second semiconductor wafer B includes no part of the dielectric layer 6′ on a side of the semiconductor active region 10 opposite the second semiconductor substrate 8, Step C may include joining or coupling together the first and second semiconductor wafers A and B, e.g., by fusion, at the interface of the dielectric layer 6 and the semiconductor active region 10. In the view shown in FIG. 1A, the second semiconductor wafer B may be inverted and disposed on top of the first semiconductor wafer A.

For the purpose of this disclosure only, it will be assumed that the second semiconductor wafer B is inverted and disposed on top of the first semiconductor wafer A. However, this is not to be construed as limiting since it is envisioned that the first semiconductor wafer A may be inverted and disposed on top of the first semiconductor wafer B. Accordingly, the various views and orientations shown in the figures are strictly for the purpose of this disclosure are not to be construed as limiting.

In another example, if, in Step B, the second semiconductor wafer B includes the entirety of the dielectric layer 6′ disposed on the semiconductor active region 10, and if, in Step A, no part of the dielectric layer 6 is disposed on the bottom DBR 4, Step C may include joining or coupling together the first and second semiconductor wafers A and B, e.g., by fusion, at the interface of the dielectric layer 6′ and the bottom DBR 4. In the view shown in FIG. 1A, the second semiconductor wafer B may be inverted and disposed on top of the first semiconductor wafer A.

In another example, if a first portion of the dielectric layer 6 is disposed in Step A on the bottom DBR 4 and if a second portion of the dielectric layer 6′ is disposed in Step B on the semiconductor active region 10, Step C may include joining or coupling together the first and second semiconductor wafers A and B, e.g., by fusion, at the interface of the first and second portions of the dielectric layers 6 and 6′, e.g., in the view shown in FIG. 1A, the second semiconductor wafer B may be inverted and disposed on top of the first semiconductor wafer A.

In an example, each dielectric layer 6 and/or 6′, or each portion thereof, may have a refractive index n≤1.5, whereupon the dielectric layer 6 and/or 6′ may be considered a low refractive index dielectric layer. However, this is not to be construed as limiting since, alternatively, each dielectric layer 6 and/or 6′ may have a refractive index n>1.5. In an example, at least following Step C, the dielectric layer(s) 6, or 6′, or 6 and 6′ may have a total thickness of λx, where x is an odd number, e.g., 1, 3, 5, etc., and λ is a wavelength of an optical signal to be produced by the VCSEL. However, this is not to be construed as limiting since the dielectric layer(s) 6, or 6′, or 6 and 6′ may have any thickness deemed suitable and/or desirable for a particular application.

In this disclosure, each dielectric layer(s) 6, or 6′, or 6 +6′ may be comprised of a single layer or multiple sublayers of the same suitable and/or desirable dielectric material, or multiple sublayers of different suitable and/or desirable dielectric materials, e.g., without limitation, SiO2 and Ta2O5.

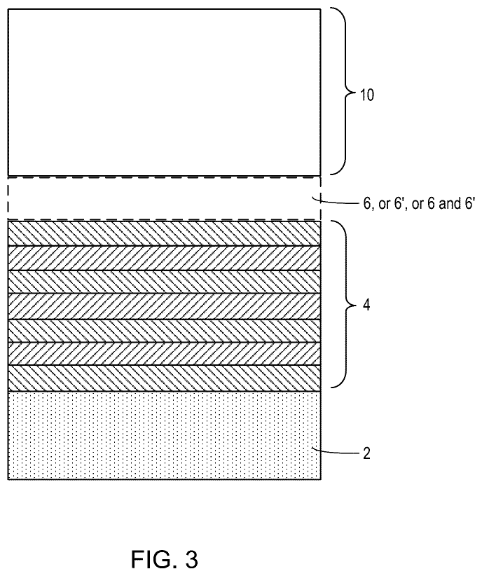

With reference to FIG. 3 and with continuing reference to all previous figures, following Step C, the method may comprise a Step D, wherein the second semiconductor substrate 8 may be removed.

With reference to FIG. 4A and with continuing reference to all previous figures, following Step D, the method may comprise a Step E. In this Step E, where the semiconductor active region 10 comprises the structure shown in FIG. 1B, the current confinement structure 20 may be formed on all or part of the sides of (e.g., surrounding) the one or more active subregions 10-1, 10-2 of the semiconductor active region 10 of the second semiconductor wafer B after fusion of the first and second semiconductor wafers A and B. In an example, the current confinement structure 20 may be formed by oxidation (to form an oxide aperture), ion implantation, or by etching and overgrowth all or part of the sides of the one or more active subregions 10-1, 10-2.

Alternatively, where the semiconductor active region 10 comprises the structure shown in FIG. 1D including the current confinement structure 20 formed in Step B prior to fusion of the first and second semiconductor wafers A and B, Step E may be omitted.

Regardless of when the current confinement structure 20 shown in FIG. 4A is formed on the semiconductor active region 10, i.e., either prior to or after fusion of the first and second semiconductor wafers A and B, the semiconductor active region 10 including the current confinement structure 20 will have the sequence and arrangement of layers as shown in FIG. 1D, except inverted due to the inversion of the second semiconductor wafer B for fusion thereof to the first semiconductor wafers A in Step C described above.

With reference to FIG. 4B and with continuing reference to all previous figures, alternatively, where the semiconductor active region 10 comprises the structure shown in FIG. 1C, the current confinement structure 20 may be formed in Step E on all or part of the sides of (e.g., surrounding) the one or more active subregions 10-1, 10-2 of the semiconductor active region 10 of the second semiconductor wafer B after fusion of the first and second semiconductor wafers A and B. In an example, the current confinement structure 20 may be formed by oxidation (to form an oxide aperture), ion implantation. or by etching and overgrowth all or part of the sides of the one or more active subregions 10-1, 10-2.

Alternatively, where the semiconductor active region 10 comprises the structure shown in FIG. 1E including the current confinement structure 20 formed in Step B prior to fusion of the first and second semiconductor wafers A and B, Step E may be omitted.

Regardless of when the current confinement structure 20 shown in FIG. 4B is formed on the semiconductor active region 10, i.e., either prior to or after fusion of the first and second semiconductor wafers A and B, the semiconductor active region 10 including the current confinement structure 20 will have the same sequence and arrangement of layers as shown in FIG. 1E, except inverted due to the inversion of the second semiconductor wafer B for fusion thereof to the first semiconductor wafers A in Step C described above.

With reference to FIG. 4C and with continuing reference to all previous figures, where the semiconductor active region 10 comprises the structure shown in FIG. 1F including the current confinement structure 20 formed in Step B prior to fusion of the first and second semiconductor wafers A and B, Step E may be omitted. Alternatively, where the semiconductor active region 10 shown in FIG. 1F excludes the current confinement structure 20 prior to wafer fusion, the current confinement structure 20 may be added to the semiconductor active region 10 in Step E after wafer fusion.

Regardless of when the current confinement structure 20 shown in FIG. 4C is formed on the semiconductor active region 10, i.e., either prior to or after fusion of the first and second semiconductor wafers A and B, the semiconductor active region 10 including the current confinement structure 20 will have the sequence and arrangement of layers as shown in FIG. 1F, except inverted due to the inversion of the second semiconductor wafer B for fusion thereof to the first semiconductor wafers A in Step C described above.

With reference to FIG. 4D and with continuing reference to all previous figures, where the semiconductor active region 10 comprises the structure shown in FIG. 1G including the current confinement structure 20 formed in Step B prior to fusion of the first and second semiconductor wafers A and B, Step E may be omitted. Alternatively, where the semiconductor active region 10 shown in FIG. 1G excludes the current confinement structure 20 prior to wafer fusion, the current confinement structure 20 may be added to the semiconductor active region 10 in Step E after wafer fusion.

Regardless of when the current confinement structure 20 shown in FIG. 4D is formed on the semiconductor active region 10, i.e., either prior to or after fusion of the first and second semiconductor wafers A and B, the semiconductor active region 10 including the current confinement structure 20 will have the sequence and arrangement of layers as shown in FIG. 1G, except inverted due to the inversion of the second semiconductor wafer B for fusion thereof to the first semiconductor wafers A in Step C described above.

With reference to FIG. 5 and with continuing reference to all previous figures, following Step E or following Step D when Step E may, as described above, be omitted, the method may comprise a Step F, wherein a top DBR 22 may be formed on a side of the semiconductor active region 10 opposite the bottom DBR 4. In an example, the top DBR 22 may be formed of alternating layers 22-1 and 22-2 of SiO2 and Ta2O5, respectively. However, this is not to be construed as limiting since the top DBR 22 may be formed of alternating layers of any suitable and/or desirable materials now known or hereafter developed that enable the top DBR 22 to function or operate in a manner known in the art. In an example, the alternating layers 22-1 and 22-2 of the top DBR 22 may be formed of materials having refractive indices <2.0 (e.g., 1.45) and >2.0 (e.g., 2.25), respectively. In an example, each layer 22-1 and 22-2 may have a thickness of λx/4, where x is an odd number, e.g., 1, 3, 5, etc., and λ is a wavelength of an optical signal produced by the VCSEL.

In an example, the top DBR 22 may comprise a first plurality of semiconductor layers; and the bottom DBR 4 may comprise a second plurality of semiconductor layers. In an example, the number of the first plurality of semiconductor layers of the top DBR 22 and the number of the second plurality of semiconductor layers of the bottom DBR 4 may be same or different.

In an example shown in FIG. 5, a grating structure 24 (shown by the solid line arrow 24 in FIG. 5) may be formed on the exposed top surface of the top DBR 22 opposite the semiconductor active region 10. In another example (shown by the dashed line arrow 24 in FIG. 5), the grating structure 24 may be formed between any pair of layers 22-1, 22-2 of the body of the second DBR 22. In yet another example (shown by the dashed-dot line arrow 24 in FIG. 5), the grating structure 24 may be formed between the semiconductor active region 10 and the bottom layer of the second DBR 22. The grating structure 24 may formed at any one or more of the positions shown by the solid line arrow 24, the dashed line arrow 24, and/or the dot-dashed line arrow 24 in FIG. 5.

In an example, the grating structure or layer 24 may be formed of the material forming a layer 22-1 or a layer 22-2 of the second DBR 22. In another example, the grating structure 24 may, also or alternatively, be formed of a material known in the art as a separate layer.

In an example, the grating structure 24 may have lines 26 of height h and a spacing k between facing sides of adjacent lines 26, wherein the values of height h and spacing k may be chosen for the wavelength of the optical signal, e.g., IR light, to be produced by the VCSEL. In an example, each line 26 of the grating structure 24 may have a grating height h between zero and a quarter wave, i.e., λ/4.

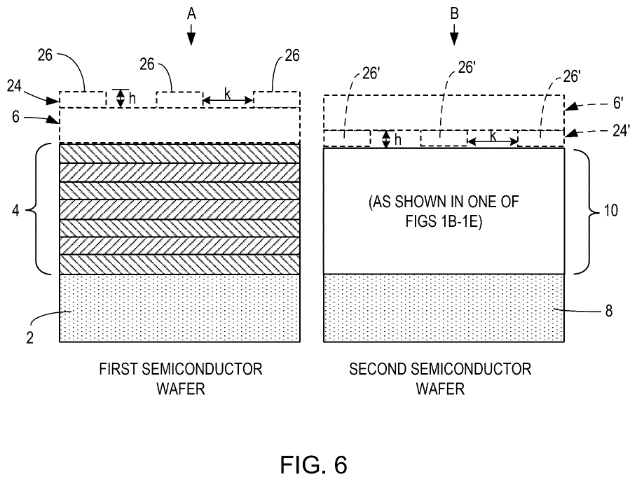

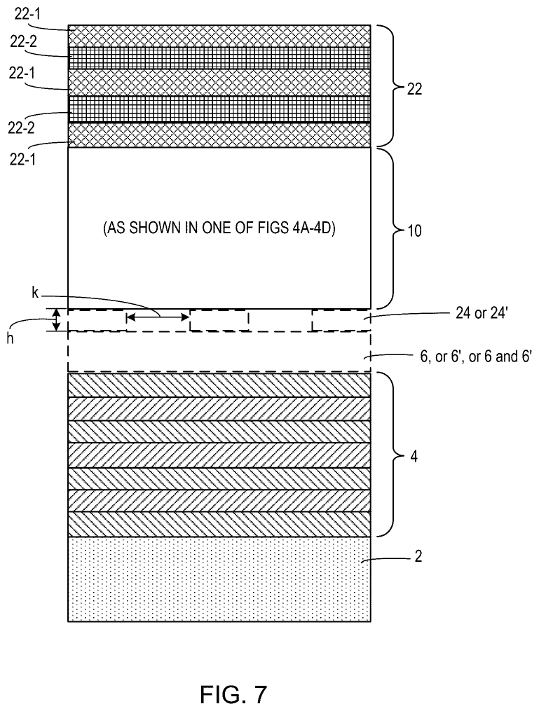

With reference to FIGS. 6 and 7 and with continuing reference to all previous figures, a method of fabricating a second example VCSEL in accordance with the principles of the present disclosure may be similar in most respects to the method of fabricating the first example VCSEL described above with reference to FIGS. 1-5 except as follows: the grating structure 24 may be formed prior to Step C.

For example, as shown in FIG. 6, where, in Step A, the first semiconductor wafer A includes the entirety of the dielectric layer 6 and, in Step B, the second semiconductor wafer B includes no part of a grating structure 24′ and the dielectric layer 6′, Step A may also comprise the first semiconductor wafer A including the grating structure 24 formed on a side of the dielectric layer 6 opposite the bottom DBR 4. In this example, Step C may include joining or coupling together the first and second semiconductor wafers A and B, e.g., by fusion, at the interface of the grating structure 24 and the semiconductor active region 10, as shown in FIG. 7.

In another example, where, in Step B, the second semiconductor wafer B includes the entirety of the dielectric layer 6′ and, in Step A, the first semiconductor wafer A includes no part of the grating structure 24 and the dielectric layer 6, Step B may also comprise the second semiconductor wafer B including the grating structure 24′ formed between the dielectric layer 6′ and the semiconductor active region 10. In this example, the dielectric layer 6′ may follow the shape and/or contour of the lines 26′ of the grating structure 24′. In this example, Step C may include joining or coupling together the first and second semiconductor wafers A and B, e.g., by fusion, at the interface of the dielectric layer 6′ and the bottom DBR 4, as shown in FIG. 7.

In another example, if Step A comprises the first semiconductor wafer A including a first portion of the dielectric layer 6 disposed on the bottom DBR 4 and no part of the grating structure 24, and Step B comprises the second semiconductor wafer B including a second portion of the dielectric layer 6′, Step B may also comprise the second semiconductor wafer B including the grating structure 24′ formed between the second portion of the dielectric layer 6′ and the semiconductor active region 10. In this example, Step C may include joining or coupling together the first and second semiconductor wafers A and B, e.g., by fusion, at the interface of the first and second portions of the dielectric layer 6 and 6′, as shown in FIG. 7.

In another example, Step A may include forming the grating structure 24 in direct contact with the side of the bottom DBR 4 opposite the first semiconductor substrate 2 and the dielectric layer 6 (or portion thereof) may be formed on a side of the grating structure 24 opposite the bottom DBR 4, i.e., the positions of the grating structure 24 and dielectric layer 6 shown in FIG. 6 may be reversed. In this example, the dielectric layer 6 (or portion thereof) may follow the shape and/or contour of the lines 26 of the grating structure 24. In this example, Step C may include joining or coupling together the first and second semiconductor wafers A and B, e.g., by fusion, at the interface of the dielectric layer 6 and the semiconductor active region 10.

In the example shown in FIGS. 6 and 7, the grating structure or layer 24 and/or 24′ (or each portion thereof) may be formed of the material forming the layer 22-1 or layer 22-2 of the second DBR 22 shown in FIG. 7. Also or alternatively, the grating structure or layer 24 and/or 24′ (or each portion thereof) may be formed of one or more suitable and/or desirable materials known in the art.

In an example, the grating structures 24 and/or 24′ shown in FIGS. 6 and 7 may have lines 26 and/or 26′ of height h and a spacing k between facing sides of adjacent lines 26, wherein the values of height h and spacing k may be chosen for the wavelength of the optical signal, e.g., IR light, to be produced by the VCSEL. In an example, each line 26 and/or 26′ may have a height h between zero and a quarter wave, i.e., λ/4.

Following Step C, the method of fabricating the second example VCSEL in accordance with the principles of the present disclosure may include Steps D, E (as needed), and F proceeding as described above for the first example VCSEL shown and described above in connection with FIGS. 1-5.

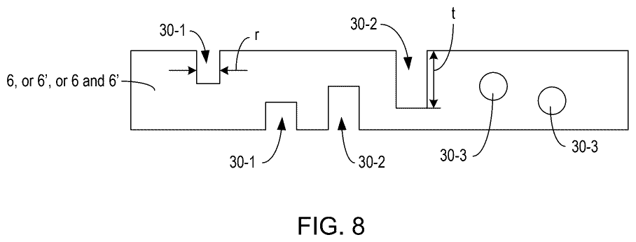

With reference to FIG. 8 and with continuing reference to all previous figures, in FIGS. 1-7 the dielectric layers 6, or 6′, or 6 and 6′ may be solid bodies. However, in accordance with the principles of the present disclosure shown in FIG. 8, it is envisioned that the bodies of the dielectric layers 6, or 6′, or 6 and 6′ shown in FIGS. 1-7 may include any number of voids, spaces, or pockets 30 of the same or different dimensions that include no material. In an example, one or more voids, spaces, or pockets 30-1 may extend a first depth into the body of the dielectric layer(s) 6, or 6′, or 6 and 6′ from one or both surfaces of the body of the dielectric layer 6. Also or alternatively, in another example, one or more voids, spaces, or pockets 30-2 may extend a second, deeper depth into or through the body of the dielectric layer(s) 6, or 6′, or 6 and 6′ from one or both surfaces of the body of the dielectric layer(s) 6, or 6′, or 6 and 6′. Also or alternatively, in another example, one or more voids, spaces, or pockets 30-3 may be formed in the interior of the body of the dielectric layer(s) 6, or 6′, or 6 and 6′, e.g., from the side of the body of the dielectric layer 6. Also or alternatively, in yet another example, the body of the dielectric layer(s) 6, or 6′, or 6 and 6′ may include any combination of two or more voids, spaces, or pockets 30-1, 30-2, and/or 30-3.

In an example, each void, space, or pocket 30 may be filled with air, having a refractive index n=1, or any other suitable and/or desirable gas or combination of gasses having a refractive index less than the refractive index of the dielectric layer(s) 6, or 6′, or 6 and 6′ (n≤2). A benefit of this is a decrease in the overall refractive index of the dielectric layer(s) 6, or 6′, or 6 and 6′ and a corresponding increase in the refractive index contrast between the dielectric layer(s) 6, or 6′, or 6 and 6′ and bottom DBR 4 in the examples shown in FIGS. 5 and 7. This means that the same bottom DBR 4 reflectivity may be achieved with a lesser number of DBR layer pairs 4-1 and 4-2. A benefit of the bottom DBR 4 having a lesser number of DBR layer pairs 4-1 and 4-2 is that the bow of the first semiconductor wafer A may be diminished and the yield of the joining or coupling together of the first and second semiconductor wafers A and B, e.g., by fusion, may be improved. Another benefit is improved thermal conductivity to the first semiconductor substrate 2 from the bottom DBR 4.

In an example, properties of each void, space, or pocket 30 may include a width or diameter r<<λ, i.e., the wavelength of the optical signal, e.g., of IR light, to be produced by the VCSEL. The height t of each void, space, or pocket 30 may be as tall as the dielectric layer(s) 6, or 6′, or 6 and 6′, i.e., may extend though the thickness of the dielectric layer 6. Each void, space, or pocket 30 may have any suitable and/or desirable shape, e.g., circular, rectangular, columnar, cylindrical, etc. Each void, space, or pocket 30 may be formed by etching the dielectric layer(s) 6, or 6′, or 6 and 6′ or by porous deposition of the material forming the dielectric layer(s) 6, or 6′, or 6 and 6′. Finally, properties of each void, space, or pocket 30 may include polarization control, namely, little or no impact on polarization of the optical signal produced by the VCSEL because the width r of each void, space, or pocket 30<<λ, whereupon each void, space, or pocket 30 has little or no diffraction.

The foregoing example VCSELs in accordance with the principles of the present disclosure may be formed by conventional semiconductor processing techniques known in the art which have not been described herein for the purpose of simplicity.

Other non-limiting examples or aspects of this disclosure are set forth in the following illustrative and exemplary numbered clauses:
Clause 1: A method of fabricating a vertical cavity surface emitting laser (VCSEL) comprises: (a) forming or providing a first semiconductor wafer comprising, from a bottom to a top thereof, a first semiconductor substrate and a bottom distributed Bragg reflector (DBR); (b) forming or providing a second semiconductor wafer comprising, from a bottom to a top thereof, a second semiconductor substrate and a semiconductor active region comprising at least one active subregion and a top cavity layer on a side of the at least one active subregion opposite the second semiconductor substrate, wherein each active subregion comprises: a pair of cavity layers separated by a tunnel junction layer and a quantum well layer on a side of the pair of cavity layers opposite the second semiconductor substrate, or a pair of cavity layers separated by a quantum well layer and a tunnel junction layer on a side of the pair of cavity layers opposite the second semiconductor substrate; (c) coupling the bottom DBR and the semiconductor active region with the second semiconductor substrate disposed on a side of the semiconductor active region opposite the bottom DBR and then removing the second semiconductor substrate; (d) following the removal of the second semiconductor substrate, forming on a side of the semiconductor active region opposite the bottom DBR a top DBR; and (e) forming on all or part of the at least one active subregion of the semiconductor active region a current confinement structure.
Clause 2: The method of clause 1, wherein: step (b) may include the semiconductor active region including two active subregions; or step (c) may include coupling the bottom DBR and the semiconductor active region with a dielectric layer therebetween.
Clause 3: The method of clause 1 or 2 may further comprise, prior to step (c), forming the dielectric layer on a side of the bottom DBR opposite the first semiconductor substrate, on a side of the semiconductor active region opposite the second semiconductor substrate, or on both, whereupon step (c) may include coupling the bottom DBR and the semiconductor active region with the dielectric layer therebetween.
Clause 4: The method of any one of clauses 1-3, wherein the dielectric layer may have a refractive index n≤1.5.
Clause 5: The method of any one of clauses 1-4, wherein: the top DBR may comprise a first plurality of semiconductor layers; and the bottom DBR may comprise a second plurality of semiconductor layers.
Clause 6: The method of any one of clauses 1-5, wherein the first plurality of semiconductor layers of the top DBR and the second plurality of semiconductor layers of the bottom DBR may be different.
Clause 7: The method of any one of clauses 1-6 may further comprise forming a grating structure: on a side of the top DBR opposite the at least one semiconductor active region; or between layers of the top DBR; or between the semiconductor active region and the top DBR; or between the bottom DBR and the semiconductor active region.
Clause 8: The method of any one of clauses 1-7, wherein the current confinement structure of step (e) may be formed prior to or after step (c).
Clause 9: The method of any one of clauses 1-8, wherein the dielectric layer may have a thickness of λx/4, where x is an odd number and λ is a wavelength of an optical signal produced by the VCSEL.
Clause 10: The method of any one of clauses 1-9, wherein the dielectric layer may include one or more voids, spaces, or pockets.
Clause 11: A vertical cavity surface emitting laser (VCSEL) comprising from a bottom to a top thereof: a semiconductor substrate; a bottom distributed Bragg reflector (DBR); a semiconductor active region comprising at least one active subregion; and a top DBR.
Clause 12: The VCSEL of clause 11, wherein the VCSEL may further comprise one of the following: a dielectric layer between the bottom DBR and the semiconductor active region; or the semiconductor active region includes two active subregions.
Clause 13: The VCSEL of clause 11 or 12, wherein the dielectric layer may have a refractive index n≤1.5.
Clause 14: The VCSEL of any one of clauses 11-13 may further comprise a current confinement structure disposed on at least part of the semiconductor active region.
Clause 15: The VCSEL of any one of clauses 11-14, wherein the current confinement structure may be formed by oxidation, ion implantation, or by etching and overgrowth of the at least part of the semiconductor active region.
Clause 16: The VCSEL of any one of clauses 11-15 may further comprise a grating structure: on a side of the top DBR layer opposite the semiconductor active region; or between layers of the top DBR; or between the semiconductor active region and the top DBR; or between the bottom DBR and the semiconductor active region.
Clause 17: The VCSEL of any one of clauses 11-16, wherein the semiconductor active region may comprise one or more active subregions each comprising one of the following: (a) a quantum well layer and a pair of cavity layers separated by a tunnel junction layer on a side of the quantum well layer opposite the dielectric layer; or (b) a tunnel junction layer and a pair of cavity layers separated by a quantum well layer on a side of the tunnel junction layer opposite the dielectric layer.
Clause 18: The VCSEL of any one of clauses 11-17 may further comprise a top cavity layer between the at least one active subregion and the dielectric layer.
Clause 19: The VCSEL of any one of clauses 11-18 may further comprise a current confinement structure disposed on at least part of each active subregion.
Clause 20: The VCSEL of any one of clauses 11-19, wherein the current confinement structure may be disposed on each cavity layer and each tunnel junction layer of each active subregion.
Clause 21: The VCSEL of any one of clauses 11-20, wherein the current confinement structure may be disposed on the quantum well layer of at least one active subregion.
Clause 22: The VCSEL of any one of clauses 11-21, wherein the dielectric layer may have a thickness of λx/4, where x is an odd number and λ is a wavelength of an optical signal produced by the VCSEL.

Although this disclosure has been described in detail for the purpose of illustration based on what is currently considered to be the most practical and preferred embodiments, it is to be understood that such detail is solely for that purpose and that the disclosure is not limited to the disclosed embodiments, but, on the contrary, is intended to cover modifications and equivalent arrangements that are within the spirit and scope of the appended claims. For example, it is to be understood that the present disclosure contemplates that, to the extent possible, one or more features of any embodiment can be combined with one or more features of any other embodiment.

What is claimed is:

1. A method of fabricating a vertical cavity surface emitting laser (VCSEL) comprising:
(a) forming or providing a first semiconductor wafer comprising, from a bottom to a top thereof, a first semiconductor substrate and a bottom distributed Bragg reflector (DBR);
(b) forming or providing a second semiconductor wafer comprising, from a bottom to a top thereof, a second semiconductor substrate and a semiconductor active region comprising at least one active subregion and a top cavity layer on a side of the at least one active subregion opposite the second semiconductor substrate, wherein each active subregion comprises:
a pair of cavity layers separated by a tunnel junction layer and a quantum well layer on a side of the pair of cavity layers opposite the second semiconductor substrate, or
a pair of cavity layers separated by a quantum well layer and a tunnel junction layer on a side of the pair of cavity layers opposite the second semiconductor substrate;
(c) coupling the bottom DBR and the semiconductor active region with the second semiconductor substrate disposed on a side of the semiconductor active region opposite the bottom DBR and then removing the second semiconductor substrate;
(d) following the removal of the second semiconductor substrate, forming on a side of the semiconductor active region opposite the bottom DBR a top DBR; and
(e) forming on all or part of the at least one active subregion of the semiconductor active region a current confinement structure.

2. The method of claim 1, wherein:
step (b) includes the semiconductor active region including two active subregions; or
step (c) includes coupling the bottom DBR and the semiconductor active region with a dielectric layer therebetween.

3. The method of claim 2, further comprising, prior to step (c), forming the dielectric layer on a side of the bottom DBR opposite the first semiconductor substrate, on a side of the semiconductor active region opposite the second semiconductor substrate, or on both, whereupon step (c) includes coupling the bottom DBR and the semiconductor active region with the dielectric layer therebetween.

4. The method of claim 2, wherein the dielectric layer has a refractive index n≤1.5.

5. The method of claim 1, wherein:
the top DBR comprises a first plurality of semiconductor layers; and
the bottom DBR comprises a second plurality of semiconductor layers.

6. The method of claim 5, wherein the first plurality of semiconductor layers of the top DBR and the second plurality of semiconductor layers of the bottom DBR are different.

7. The method of claim 1, further comprising forming a grating structure:
on a side of the top DBR opposite the at least one semiconductor active region; or
between layers of the top DBR; or
between the semiconductor active region and the top DBR; or
between the bottom DBR and the semiconductor active region.

8. The method of claim 1, wherein the current confinement structure of step (e) is formed prior to or after step (c).

9. The method of claim 2, wherein the dielectric layer has a thickness of λx/4, where x is an odd number and λ is a wavelength of an optical signal produced by the VCSEL.

10. The method of claim 2, wherein the dielectric layer includes one or more voids, spaces, or pockets.

11. A vertical cavity surface emitting laser (VCSEL) comprising from a bottom to a top thereof:
a semiconductor substrate;
a bottom distributed Bragg reflector (DBR);
a semiconductor active region comprising at least one active subregion; and
a top DBR.

12. The VCSEL of claim 11, wherein the VCSEL further comprises one of the following:
a dielectric layer between the bottom DBR and the semiconductor active region; or
the semiconductor active region includes two active subregions.

13. The VCSEL of claim 12, wherein the dielectric layer has a refractive index n≤1.5.

14. The VCSEL of claim 11, further comprising a current confinement structure disposed on at least part of the semiconductor active region.

15. The VCSEL of claim 14, wherein the current confinement structure is formed by oxidation, ion implantation, or by etching and overgrowth of the at least part of the semiconductor active region.

16. The VCSEL of claim 12, further including a grating structure:
on a side of the top DBR layer opposite the semiconductor active region; or
between layers of the top DBR; or
between the semiconductor active region and the top DBR; or
between the bottom DBR and the semiconductor active region.

17. The VCSEL of claim 11, wherein the semiconductor active region comprises one or more active subregions each comprising one of the following:
(a) a quantum well layer and a pair of cavity layers separated by a tunnel junction layer on a side of the quantum well layer opposite the dielectric layer; or
(b) a tunnel junction layer and a pair of cavity layers separated by a quantum well layer on a side of the tunnel junction layer opposite the dielectric layer.

18. The VCSEL of claim 12, further comprising a top cavity layer between the at least one active subregion and the dielectric layer.

19. The VCSEL of claim 17, further comprising a current confinement structure disposed on at least part of each active subregion.

20. The VCSEL of claim 19, wherein the current confinement structure is disposed on each cavity layer and each tunnel junction layer of each active subregion.

21. The VCSEL of claim 20, wherein the current confinement structure is disposed on the quantum well layer of at least one active subregion.

22. The VCSEL of claim 12, wherein the dielectric layer has a thickness of λx/4, where x is an odd number and λ is a wavelength of an optical signal produced by the VCSEL.
